(19) United States
(12) Patent Application Publication
(10) Pub. No.: US 2013/0078825 A1
(43) Pub. Date: Mar. 28, 2013

(54) METHOD FOR CONNECTING PRINTED CIRCUIT BOARDS

(71) Applicant: Richard Mark Wain, Newtown (GB)

(72) Inventor: Richard Mark Wain, Newtown (GB)

(21) Appl. No.: 13/611,592

(22) Filed: Sep. 12, 2012

(30) Foreign Application Priority Data
Sep. 23, 2011 (GB) GB1116522.2

(51) Int. Cl. H01R 12/52; H05K 3/36

(52) U.S. Cl. 439/64; 29/830

(57) ABSTRACT

There is provided a first, connecting printed circuit board (PCB) and a second, receiving PCB and a method for connecting the first and second PCBs. The first PCB has three projections or prongs extending from the main body of the PCB. The second PCB has three holes into which the prongs of the first PCB can be inserted to provide a secure mechanical connection whilst the PCBs are soldered together.

### CROSS-REFERENCE TO RELATED APPLICATION

This application claims the benefit and priority of Great Britain Application No. GB 1116522.2 filed Sep. 23, 2011. The entire disclosure of the above application is incorporated herein by reference.

### FIELD

The invention relates to printed circuit boards and to a method for connecting printed circuit boards.

### BACKGROUND

Printed circuit boards (PCBs) are widely used in electronics applications and are well known. In some applications it is necessary to join one PCB to another. The joining technique must provide a reliable electronic connection between the electronic contacts of the first PCB and the electronic contacts of the second PCB, as well a reliable mechanical connection between the two PCBs with accurate orientation.

One technique for providing electronic connections on and between PCBs is known as wave soldering. In the wave soldering process, a quantity of molten solder is contained within a tank. A pattern of standing waves is induced on the surface of the molten solder and the PCB to be soldered is conveyed over the surface of the molten solder. The height of the standing waves is adjusted such that the peaks of the waves contact the surface of the PCB, thereby applying solder to the PCB. To join two PCBs together in this way, the use of a mechanical support or a jig is required to hold the PCBs in the desired orientation during application of the solder. Amongst the disadvantages of the wave soldering technique are the requirements for relatively large, expensive equipment and a large quantity of solder when joining two PCBs. Additionally, the wave soldering technique is not generally suitable for modern components having many small contact areas.

Reflow soldering is a known technique for providing electronic connections between components via a PCB in which a solder paste is applied between one or more electrical components and their contact pads on a PCB. The solder paste temporarily secures the electrical components in place. The PCB and the electrical components are then heated, thereby melting the solder. As the assembly cools, the solder solidifies and permanently connects the electrical components to the PCB.

Reflow soldering is advantageous over wave soldering in that it is cleaner, quicker and can be fully automated. Using reflow soldering, modern components which have many small legs or contact areas can be soldered. However, reflow soldering precludes the use of a jig or mechanical support because the jig or mechanical support will obstruct the heating process, thereby preventing the melting of the solder. Furthermore, the jig or mechanical support cannot be put in place automatically, hence it would negate one of the key advantages of the reflow soldering technique.

### SUMMARY

According to an aspect, a method for joining a first PCB and a second PCB is provided. The first PCB has a shape defined by one or more edges and includes a connecting edge. The connecting edge has one or more electrical contacts disposed thereon and comprises one or more prongs extending therefrom. The second PCB comprises one or more electrical contacts and one or more holes for receiving the prongs of the first PCB. The method comprises connecting the first PCB to the second PCB by locating the prongs of the first PCB into the holes of the second PCB, and soldering the first PCB to the second PCB.

Because the prongs of the first PCB are located into the holes of the second PCB, a secure mechanical connection is provided between the first and second PCBs before the soldering process takes place. Thus, no external mechanical support or jig is required when soldering the first and second PCBs using any soldering process. Furthermore, because no external mechanical support or jig is required, a reflow soldering process can be employed to join the first and second PCBs.

Optionally, the first PCB comprises a substantially planar body and has at least three prongs. The prongs of the first PCB can be deflected in a direction substantially perpendicular to the plane of the first PCB. The second PCB comprises at least three holes, wherein the centre of one or more of the at least three holes is displaced from an axis passing through the centres of another two of the at least three holes. The step of locating the prongs of the first PCB into the holes of the second PCB includes deflecting the prongs of the first PCB substantially into the configuration of the holes of the second PCB.

Because the prongs of the first PCB are deflected substantially into the configuration of the holes of the second PCB, the prongs of the first PCB form a “tripod” shape, providing enhanced stability and further securing the mechanical connection between the first and second PCBs by providing leverage for resisting lateral forces on the PCBs. Thus the PCBs can be held in a desired orientation for soldering very effectively.

### BRIEF DESCRIPTION OF THE DRAWINGS

Specific embodiments are described below by way of example only and with reference to the accompanying drawings, in which:

FIG. 1 shows a connecting PCB;

FIG. 2 shows a receiving PCB; and

FIG. 3 shows the connecting PCB of FIG. 1 connected to the receiving PCB of FIG. 2.

### OVERVIEW

In overview, a first, connecting PCB is provided. The first PCB has three projections or prongs extending from the main body of the PCB. A second, receiving PCB is provided, the second PCB having three holes into which the prongs of the first PCB can be inserted, thereby providing a secure mechanical connection during the soldering process.

### DETAILED DESCRIPTION

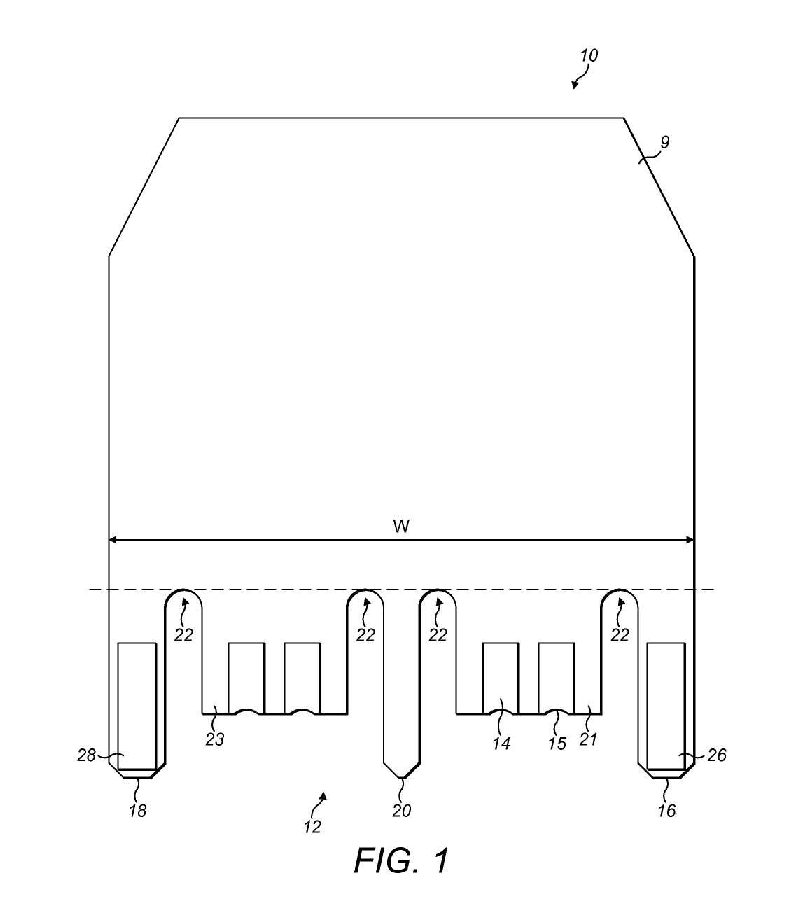

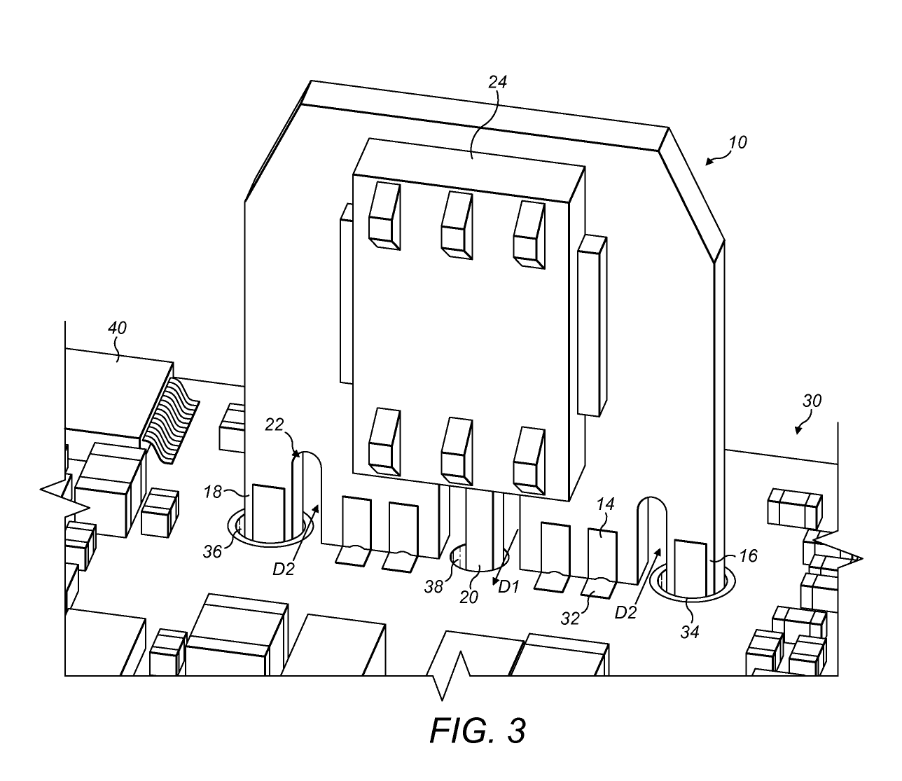

FIG. 1 shows a first PCB 10. The first PCB 10 is thin and substantially flat. Its shape is defined by a plurality of substantially straight edges and an edge having a varied profile across its width (W), referred to herein as a “connecting edge” 12. One or more electrical contacts 14 are provided on the connecting edge 12. The electrical contacts 14 can be electrically coupled to one or more electronic components 24 provided on the first PCB 10, as shown in FIG. 3.

The connecting edge 12 comprises three prongs 16, 18, 20. In the PCB shown in FIG. 1, a first prong 16 is provided at a first end of the connecting edge 12, a second prong 18 is provided at a second, distal end of the connecting edge 12 and a third prong 20 is provided generally at the centre of the connecting edge 12, in between the first 16 and second 18 prongs. The first 16 and second 18 prongs have a first plating 26 and a second plating 28 respectively, for receiving solder, as discussed in more detail below.

As mentioned above, the PCB 10 is thin and so the prongs 16, 18, 20 have a small depth (usually just a few millimetres). The prongs 16, 18, 20 each project outwardly from and substantially co-planar to a main body 9 (shown upward of the broken line in FIG. 1) of the first PCB 10, in a direction generally perpendicular to the width (W) of the connecting edge 12. Each of the prongs 16, 18, 20 has a width that is equal to or greater than its thickness, such that the prongs 16, 18, 20 can be flexed in a direction perpendicular to the plane of the first PCB 10.

According to an embodiment, each of the prongs 16, 18, 20 has a width of approximately 1 mm to 1.5 mm, a thickness or depth of approximately 1 mm to 1.5 mm and projects outwardly from the main body 9 of the first PCB 10 by a distance of approximately 1 mm to 1.5 mm.

The profile of the connecting edge 12 further defines first 21 and second 23 tabs. The first tab 21 is provided intermediate the first 16 and third 20 prongs, with recesses 22 separating the tab 21 from each of the prongs 16, 20 adjacent thereto. The second tab 23 is provided intermediate the third 20 and second 18 prongs, again with recesses separating the tab 23 from the adjacent prongs 18, 20. In the PCB 10 shown in FIG. 1, the tabs 21, 23 are wider than each of the prongs 16, 18, 20. The prongs 16, 18, 20 project outwardly from the main body 9 of the first PCB 10, in a direction perpendicular to the width (W) of the connecting edge 12, to a greater extent than the tabs 21, 23 do. The above-mentioned electrical contacts 14 are provided on the tabs 21, 23.

The recesses 22 between the tabs 21, 23 and the prongs 16, 18, 20 further enable the prongs 16, 18, 20 to be flexed in a direction perpendicular to the plane of the first PCB 10. Each of the recesses 22 has a width of approximately 1 mm.

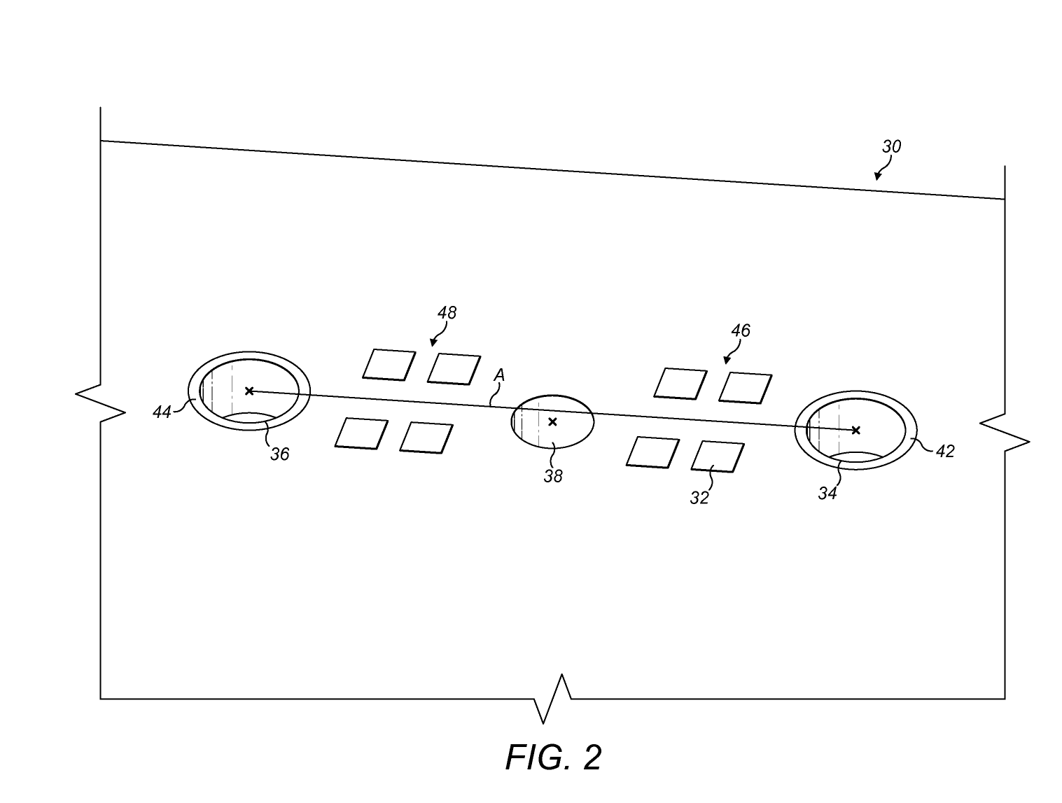

FIG. 2 shows a section of a second, receiving PCB 30. The second PCB 30 has one or more electrical contacts 32 provided on a surface thereof. The electrical contacts 32 can be electrically coupled to one or more electronic components 40 provided on the second PCB 30. As will be understood further from the description below, the electrical contacts 32 of the second PCB 30 substantially correspond in size and layout to the electrical contacts 14 of the first PCB 10.

The second PCB 30 shown in FIG. 2 has a first hole 34, a second hole 36 and a third hole 38. The third hole 38 is provided between the first 34 and second 36 holes on a surface of the second PCB 30. The distances between the first 34 and third 38 holes and between the second 36 and third 38 holes substantially correspond to the distances between the first 16 and third 20 prongs and between the second 18 and third 20 prongs of the first PCB 10, respectively. The sizes and shapes of the holes 34, 36, 38 substantially correspond to the sizes and shapes of the prongs 16, 18, 20, respectively.

The first hole 34 includes a first plating 42 and the second hole 36 includes a second plating 44. Each plating 42, 44 comprises a metallic ring around the edge that is defined by the respective hole 34, 36 for receiving solder, as discussed in more detail below.

The above mentioned electrical contacts 32 on the second PCB 30 are provided in first 46 and second 48 groups. The first group 46 of electrical contacts 32 is provided intermediate the first 34 and third 38 holes and the second group 48 of electrical contacts 32 is provided intermediate the third 38 and second 36 holes.

In FIG. 2, the centre of the first hole 34 and the centre of the second hole 36 lie on a common axis (A). The axis (A) also passes across the third hole 38, but the centre of the third hole 38 is offset from the axis (A). Therefore the holes 34, 36, 38 form a triangular configuration. According to an embodiment, the centre of the third hole 38 is offset from the axis (A) by a distance of approximately 0.5 mm.

The first 10 and second 30 PCBs can be manufactured using any suitable material. According to an embodiment, they are manufactured from glass fill epoxy resin. The electrical contacts 14, 26, 28, 32, 34, 36 are preferably manufactured from copper. In order to manufacture the first PCB 10 with copper on an edge thereof, arced recesses 15 can be provided on the distal ends of the electrical contacts 14 on the connecting edge 12 of the first PCB 10.

It is possible to form an electrical connection and a mechanical connection between the first 10 and second 30 PCBs. FIG. 3 shows the first PCB 10 and the second PCB 30 when connected. In the configuration shown, the prongs 16, 18, 20 of the first PCB 10 are located in the holes 34, 36, 38 of the second PCB 30, respectively. The electrical contacts 14 of the first PCB 10 are in contact with the electrical contacts 32 of the second PCB 30, thus enabling electrical connection between the electrical components 24 provided on the first PCB 10 and the electrical components 40 provided on the second PCB 30.

Because the prongs 16, 18, 20 project outwardly from the main body 9 of the first PCB 10 further than the tabs 21, 24 do, the prongs 16, 18, 20 can project into or even through the holes 34, 36, 38 of the second PCB 30 whereas the ends of the tabs 21, 23 rest substantially flush with the planar upper surface of the second PCB 30. The prongs 16, 18, 20 may project through the holes 34, 36, 38 such that the prongs 16, 18, 20 extend out of an opposite face of the second PCB 30, or the prongs 16, 18, 20 may project only part of the way through the holes 34, 36, 38. Arranging the prongs 16, 18, 20 to project only part of the way through the holes 34, 36, 38, improves the quality of the soldering which can be achieved between the PCBs 10 and 30.

By locating the prongs 16, 18, 20 in the holes 34, 36, 38, a secure mechanical connection between the first PCB 10 and the second PCB 30 is provided. The substantial correspondence between the relative sizes and shapes of the prongs 16, 18, 20 and the holes 34, 36, 38 serves to further enhance the secure mechanical connection.

Additionally, because the centre of the third hole 38 is displaced from the axis (A) defined between the centres of the first 34 and second 36 holes, when the first PCB 10 and the second PCB 30 are connected, the third prong 20 is bent or deflected in a direction substantially perpendicular to the plane of the first PCB 10 (shown by arrow D1 in FIG. 3). The first and second prongs 16, 18 are also bent or deflected in a direction opposite the direction in which the third prong 20 is bent or deflected (shown by arrow D2 in FIG. 3), perpendicular to the plane of the first PCB 10. The prongs 16, 18, 20 thus form a “tripod”. Because of the nature of the tripod configuration, at least one of the three prongs 16, 18, 20 is deflected away from the plane defined by the face of the first PCB 10. Leverage is therefore provided for resisting lateral forces, and so the first PCB 10 and second PCB 30 are held in the desired orientation very effectively. Additionally, when the first PCB 10 is positioned vertically and the second PCB 30 is positioned horizontally with respect to the ground, the centre of gravity of the first PCB 10 falls within the prongs 16, 18, 20, thus providing additional stability to the assembly.

Once a mechanical connection has been formed between the PCBs 10, 30, they can be electrically connected using a soldering process. Advantageously, because of the secure mechanical connection between the first 10 and second 30 PCBs, the electrical contacts 14 can be soldered to the electrical contacts 32 using a wave soldering technique without the use of any additional mechanical support such as a jig to secure the first PCB 10 and the second PCB 30 together during the soldering process.

Furthermore, because no jig is required, a reflow soldering process may advantageously be used to solder the first PCB 10 to the second PCB 30. This is particularly useful for modern electrical components, as explained in the background section above.

During the soldering process, the plating 26, 28 of the first and second prongs 16, 18 can be soldered to the plating 42, 44 of the first and second holes 34, 36 to further secure the mechanical connection between the first PCB 10 and the second PCB 30.

Although the PCBs 10, 30 are described above as having a plurality of substantially straight edges, the shape of one or both of the PCBs can be defined by any of one or more arced or irregular edges, a circular edge, or any combination or arced, circular, straight and irregularly-shaped edges. The connecting edge itself may also comprise any of (or any combination of) arced, circular and straight edges, or may have an irregular shape.

Whilst the first PCB 10 has been described as having three prongs 16, 18, 20 and the second PCB 30 has been described as having three corresponding holes 34, 36, 38, the first PCB 10 can have one, two, four or more prongs and the second PCB 30 can have one, two, four or more holes. The first PCB 10 can have a greater number of prongs than the number of holes in the second PCB 30, and likewise the second PCB 30 can have a greater number of holes than the number of prongs of the first PCB 10. For example, the second PCB 30 may have a first, elongated hole or slit into which the first 16 and second 18 prongs of the first PCB 10 can be located, and the second PCB 30 may have a second hole into which the third prong 20 of the first PCB 10 can be located. One or more of the prongs may be offset from the plane of the main body of the first PCB 10, such that little or no bending or deflection is required to insert the prongs into the holes in the second PCB 30.

Two or more first PCBs 10 may be connected to a second PCB 30 by providing additional holes 34, 36, 38 and electrical contacts 32 on the second PCB 30. Additionally or alternatively, a chain of two or more PCBs each having the features of both the first PCB 10 and the second PCB 30 disclosed above can be connected together.

In the PCBs described above, the platings 26, 28, 42, 44 are included on the first 16 and second 18 prongs of the first PCB 10 and in the first 34 and second 36 holes of the second PCB 30. These platings may be omitted. Additionally or alternatively, platings could be provided on the third prong 20 and in the third hole 38, or platings could be provided on any combination of the first 16, second 18 and third 20 prongs and first 34, second 36 and third 38 holes.

Whilst the above description relates to connecting together two PCBs, it should be readily appreciated that the techniques disclosed herein may be used in any application where a secure mechanical connection is required between two electronic components during a soldering process.

1. A method for joining a first printed circuit board (PCB) and a second PCB,
the first PCB having a shape defined by one or more edges including a connecting edge, the connecting edge having one or more electrical contacts disposed thereon, the connecting edge comprising three or more prongs,
the second PCB comprising one or more electrical contacts and three or more holes for receiving the prongs of the first PCB, wherein the centre of one of the three or more holes is displaced from an axis passing through the centres of another two of the three or more holes, the method comprising:
connecting the first PCB to the second PCB by locating the prongs of the first PCB into the holes of the second PCB; and
soldering the first PCB to the second PCB,
wherein the step of locating the prongs of the first PCB into the holes of the second PCB includes deflecting the prongs of the first PCB substantially into the configuration of the holes of the second PCB.

2. A method as claimed in claim 1, wherein one or more of the three or more prongs comprise a plating for receiving solder and one or more of the three or more holes comprise a plating for receiving solder, the method further comprising soldering the plating of the one or more prongs to the plating of the one or more holes.

3. A method as claimed in claim 1, wherein the step of soldering the first PCB to the second PCB is performed using wave soldering.

4. A method as claimed in claim 1, wherein the step of soldering the first PCB to the second PCB is performed using reflow soldering.

5. An assembly comprising a first printed circuit board (PCB) and a second PCB,
the first PCB having a shape defined by one or more edges including a connecting edge, the connecting edge having one or more electrical contacts disposed thereon, the connecting edge comprising three or more prongs,
the second PCB comprising one or more electrical contacts and three or more holes for receiving the prongs of the first PCB, wherein the centre of one of the three or more holes is displaced from an axis passing through the centres of another two of the three or more holes,
wherein the prongs of the first PCB are located in the holes of the second PCB, and wherein the prongs of the first PCB, when located in the holes of the second PCB, are deflected substantially into the configuration of the holes of the second PCB.

6. A printed circuit board (PCB) having a shape defined by one or more edges, including a connecting edge, the connecting edge having one or more electrical contacts disposed thereon, wherein the connecting edge comprises three or more prongs, wherein the PCB includes a substantially planar body, and wherein the prongs extend outwardly from and substantially co-planar to said body and are arranged to be deflected in a direction substantially perpendicular to the body.

7. A printed circuit board as claimed in claim 6, wherein the one or more electrical contacts are disposed on one or more respective tabs, wherein the three or more prongs extend outwardly from the body of the PCB to a greater extent than the tabs do.

8. A printed circuit board as claimed in claim 6, wherein the connecting edge further includes one or more recesses adjacent to the three or more prongs.

9. A printed circuit board as claimed in claim 8, wherein each of said recesses is provided intermediate a prong and a tab along the connecting edge.

10. A printed circuit board as claimed in claim 6, wherein one or more of the three or more prongs comprise a plating for receiving solder.

11. A printed circuit board (PCB) comprising one or more electrical contacts and three or more holes for receiving three or more prongs of a PCB as claimed in claim 6, wherein the centre of one of the three or more holes is displaced from an axis passing through the centres of another two of the three or more holes.

12. A printed circuit board as claimed in claim 11, wherein the holes are provided in a triangular configuration.

13. A printed circuit board as claimed in claim 11, wherein the electrical contacts are provided intermediate the holes.

14. A printed circuit board as claimed in claim 11, wherein one or more of the three or more holes comprise a plating for receiving solder.

15. A method as claimed in claim 2, wherein the step of soldering the first PCB to the second PCB is performed using wave soldering.

16. A method as claimed in claim 2, wherein the step of soldering the first PCB to the second PCB is performed using reflow soldering.

17. A printed circuit board as claimed in claim 7, wherein the connecting edge further includes one or more recesses adjacent to the three or more prongs.

18. A printed circuit board as claimed in claim 7, wherein one or more of the three or more prongs comprise a plating for receiving solder.

19. A printed circuit board as claimed in claim 8, wherein one or more of the three or more prongs comprise a plating for receiving solder.

20. A printed circuit board as claimed in claim 9, wherein one or more of the three or more prongs comprise a plating for receiving solder.
